(19) United States
(12) Patent Application Publication
(10) Pub. No.: US 2022/0121246 A1
(43) Pub. Date: Apr. 21, 2022

(54) DOUBLE-SHAFT HINGE WITH STABLE STRUCTURE

(71) Applicant: Sinher Technology Inc., New Taipei City (TW)

(72) Inventors: Yung-Chang CHIANG, New Taipei City (TW); Kuei-Shen CHEN, New Taipei City (TW)

(21) Appl. No.: 17/494,452

(22) Filed: Oct. 5, 2021

(30) Foreign Application Priority Data
Oct. 16, 2020 (TW) 109213635

(51) Int. Cl. G06F 1/16; H05K 7/16

(52) U.S. Cl. CPC G06F 1/1681; H05K 7/16

(57) ABSTRACT

A double-shaft hinge with a stable structure includes a first rotating shaft, a second rotating shaft, a carrier frame and a switching sheet. The first rotating shaft is provided with a first cam; the second rotating shaft is parallel to the first rotating shaft and is provided with a second cam; the carrier frame is formed with a limiting passage and two shaft installation holes for the first rotating shaft and the second rotating shaft to pass through respectively; the switching sheet is arranged on the carrier frame and limited by the limiting passage and only makes a linear movement along a surface of the carrier frame. The switching sheet has a first state of being pushed by the first cam to limit the rotation of the second rotating shaft, and a second state of being pushed by the second cam to limit the rotation of the first rotating shaft.

### FIELD OF THE INVENTION

The present invention relates to a double-shaft hinge, and in particular, a double-shaft hinge with a stable structure.

### BACKGROUND OF THE INVENTION

Most of the existing double-shaft hinges control the movement of rotating shafts through switching sheets. The double-shaft hinge includes a first rotating shaft, a second rotating shaft, a carrier frame used for the first rotating shaft and the second rotating shaft to pass through, a connecting assembly arranged at one side of the carrier frame and connected with the first rotating shaft and the second rotating shaft, and a switching assembly arranged on the carrier frame and subjected to the action of the first rotating shaft and the second rotating shaft. The double-shaft hinge is provided as in Japan Patent No. 5704613 and Taiwan Patent No. 1518479. However, as for the provided double-shaft hinge, the structure of the double-shaft hinge is cumbersome, which leads to complex assembling procedures of the operation personnel, resulting in difficult assembling.

Moreover, although the applicant filed Taiwan Patent No. M469727 before, the double-shaft hinge provided in the patent was not provided with the connecting assembly, which was convenient for the operation personnel to assemble. However, the applicant noticed that the double-shaft hinge still had disadvantages in practice. For example, in order to prevent the switching sheet from falling off of the carrier frame during the movement, the double-shaft hinge was provided with a limiting part on the carrier frame. However, the applicant noticed that the structural strength of the limiting part was insufficient, so the double-shaft hinge fails to meet the requirements of shock resistance. When the double-shaft hinge fell to the ground from a certain height, the limiting part broke easily, and the switching sheet was separated from the carrier frame easily.

### SUMMARY OF THE INVENTION

A main objective of the present invention is to solve the problems of insufficient structural strength of the existing double-shaft hinge.

In order to attain the above objective, the present invention provides a double-shaft hinge with a stable structure, which includes a first rotating shaft, a second rotating shaft, a carrier frame and a switching sheet. The first rotating shaft is provided with a first cam; the second rotating shaft is parallel to the first rotating shaft and is provided with a second cam; the carrier frame is formed with a limiting passage and two shaft installation holes that are arranged at intervals and used respectively for the first rotating shaft and the second rotating shaft to pass through; openings in two ends of the limiting passage face the first cam and the second cam respectively; the switching sheet is arranged on the carrier frame and limited by the limiting passage to make a linear movement only along a surface of the carrier frame; and the switching sheet has a first state of being pushed by the first cam to limit rotation of the second rotating shaft, and a second state of being pushed by the second cam to limit rotation of the first rotating shaft.

In an embodiment, the carrier frame includes a main body formed with the two shaft installation holes, two retaining walls located respectively between the two shaft installation holes and parallel to the linear movement, and a cover disposed on the two retaining walls. The main body, the two retaining walls and the cover jointly define the limiting passage.

In an embodiment, the main body is formed with a through hole arranged between the two shaft installation holes; the switching sheet is formed with an elongated hole; the cover is provided with a convex column extending into the through hole via the elongated hole; and a position of the convex column in the elongated hole is changed when the switching sheet makes the linear movement.

In an embodiment, the first cam and the second cam are provided respectively with a rotation limiting block at one side facing the main body; and the carrier frame is provided with a retaining block matched with the rotation limiting block respectively at one sides facing the first cam and the second cam.

In an embodiment, a height of the limiting passage is greater than or equal to a thickness of the switching sheet.

In an embodiment, the double-shaft hinge is provided with at least one torsion generating member arranged at one side of the carrier frame and connected with the first rotating shaft and the second rotating shaft. The at least one torsion generating member is provided with a connecting arm connected with one of the first rotating shaft and the second rotating shaft, and an open hole used for the other one of the first rotating shaft and the second rotating shaft to pass through.

In an embodiment, the double-shaft hinge is provided with at least one connecting sheet connected with the first rotating shaft and the second rotating shaft and two torsion spring groups arranged respectively on the first rotating shaft and the second rotating shaft.

According to the above description, compared with the conventional technique, the present invention has following characteristics: the carrier frame is provided with the limiting passage, so that the switching sheet is limited by the limiting passage to make the linear movement along a surface of the carrier frame, thereby preventing the switching sheet from falling off of the carrier frame. Moreover, the double-shaft hinge of the present invention has better structural stability and gives a better experience to the user.

### BRIEF DESCRIPTION OF THE DRAWINGS

FIG. 1 is a schematic diagram of an appearance of a first embodiment of the present invention.

FIG. 2 is an exploded perspective view of the first embodiment of the present invention.

FIG. 3 is a partial section view of the first embodiment of the present invention.

FIG. 4 is a first cross-section diagram of the first embodiment of the present invention.

FIG. 5 is a second cross-section diagram of the first embodiment of the present invention.

FIG. 6 is an exploded perspective view of a second embodiment of the present invention.

FIG. 7 is a partial section view of the second embodiment of the present invention.

### DETAILED DESCRIPTION OF THE PREFERRED EMBODIMENTS

The detailed description and technical content of the present invention are described below with reference to the accompanying drawings.

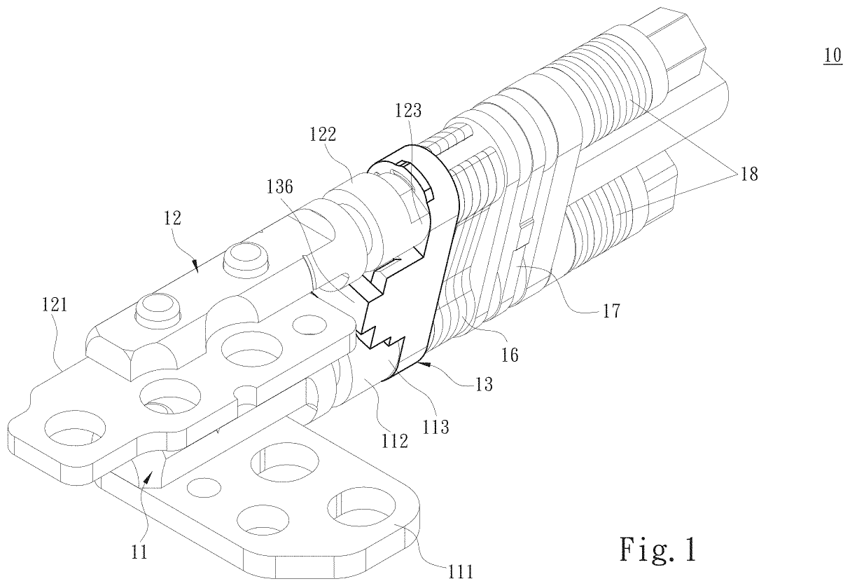

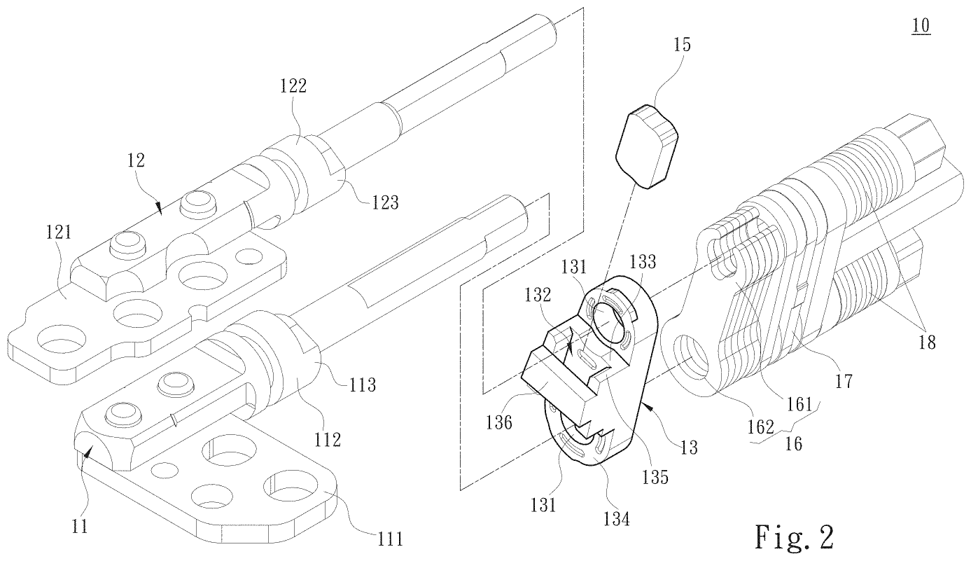

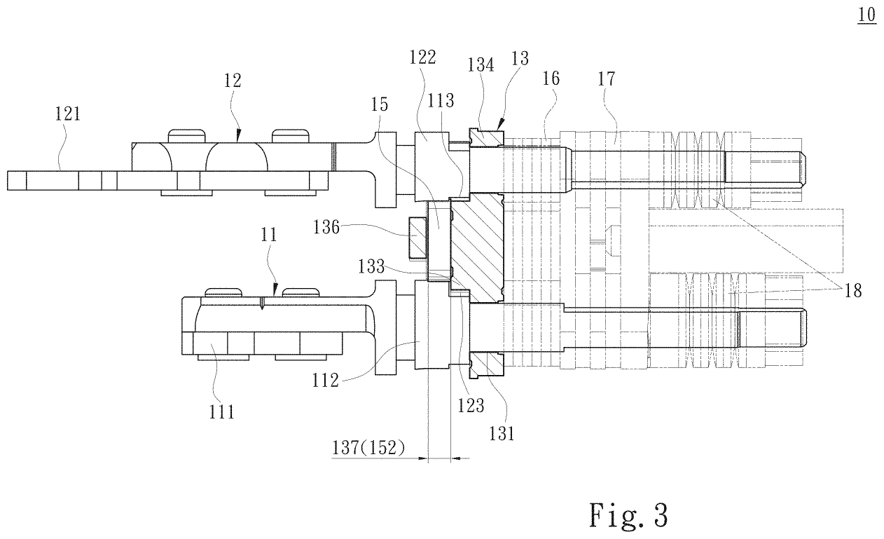

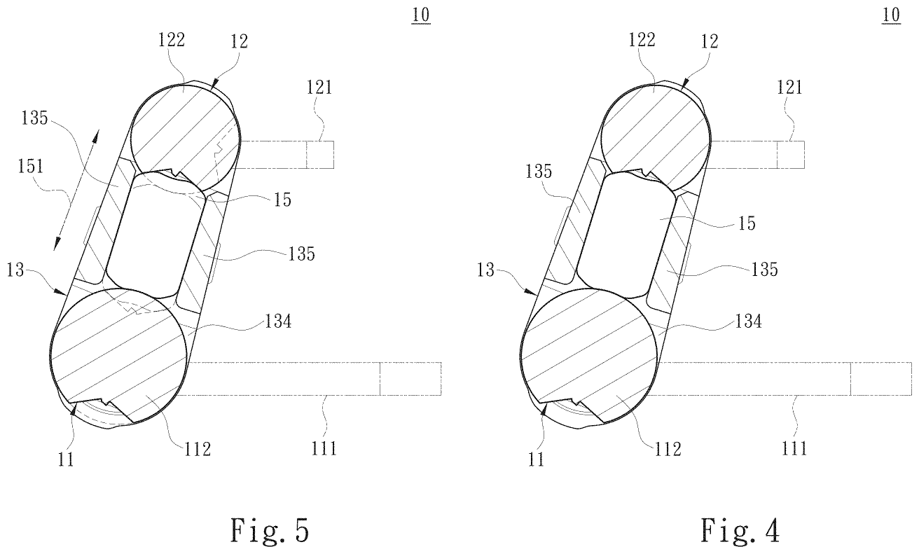

Referring to FIG. 1, FIG. 2, FIG. 3, FIG. 4, and FIG. 5, the present invention provides a double-shaft hinge 10 with a stable structure. The double-shaft hinge 10 comprises a first rotating shaft 11, a second rotating shaft 12, a carrier frame 13 and a switching sheet 15. Each of the rotating shafts is connected with an external component. For example, the first rotating shaft 11 is provided with a first assembling plate 111, and the second rotating shaft 12 is provided with a second assembling plate 121. Each of the assembling plates is connected with the external component. The external component is a base assembly or a display screen of an electronic product according to implementation requirements. Further, the first rotating shaft 11 is provided with a first cam 112; the second rotating shaft 12 is parallel to the first rotating shaft 11, and the second rotating shaft 12 is provided with a second cam 122; the position of the second cam 122 on the second rotating shaft 12 corresponds to the position of the first cam 112 on the first rotating shaft 11, that is, the second cam 122 and the first cam 112 are located at the same height of the two shafts.

Further, the carrier frame 13 is connected with the first rotating shaft 11 and the second rotating shaft 12. The carrier frame 13 comprises two shaft installation holes 131 and a limiting passage 132 between the two shaft installation holes 131. Each of the two shaft installation holes 131 are arranged at intervals and is located at two sides of the carrier frame 13. The two shaft installation holes 131 are respectively for the first rotating shaft 11 and the second rotating shaft 12 to pass through. The first cam 112 and the second cam 122 are located on the same side of the carrier frame 13; and two opening ends of the limiting passage 132 respectively face the first cam 112 and the second cam 122. Further, the switching sheet 15 is arranged on the carrier frame 13 and located in the limiting passage 132. Two sides of the switching sheet 15 face the first rotating shaft 11 and the second rotating shaft 12 respectively. When the switching sheet 15 is under the action of the first rotating shaft 11 or the second rotating shaft 12, the switching sheet 15 is limited by the limiting passage 132 and only moves in the limiting passage 132 and makes a linear movement 151 on a surface of the carrier frame 13. More specifically, the switching sheet 15 has a first state of being pushed by the first cam 112 when the first rotating shaft 11 is forced to rotate, and a second state of being pushed by the second cam 122 when the second rotating shaft 12 is forced to rotate.

To explain the implementation of the double-shaft hinge 10, firstly, when the double-shaft hinge 10 is closed, that is, the first assembling plate 111 and the second assembling plate 121 are horizontal (equivalent to a state where a display device of an electronic apparatus is flush with the base assembly), as shown in FIG. 4. In the meantime, the switching sheet 15 is pushed by the first cam 112 and is in the first state, the second rotating shaft 12 is limited, and the first rotating shaft 11 is not limited. That is, the first rotating shaft 11 rotates when forced. When the user applies force to open the display device, the first rotating shaft 11 is forced to rotate, and the rotation of the first rotating shaft 11 drives the first cam 112. Therefore, the first cam 112 contacts and pushes the switching sheet 15 during the rotation, and the switching sheet 15 makes the linear movement 151 towards the second cam 122 along the surface of the carrier frame 13. Subsequently, when the switching sheet 15 moves, the second rotating shaft 12 is not limited, that is, the second rotating shaft 12 may rotate about the carrier frame 13. When the second rotating shaft 12 is operated, the second cam 122 pushes the switching sheet 15, so that the switching sheet 15 makes the linear movement 151 towards the first rotating shaft 11. After the displacement of the switching sheet 15, the switching sheet 15 enters the second state from the first state, and the switching sheet 15 pushes against the first cam 112 to limit the first rotating shaft 11. For example, in order to close the double-shaft hinge 10, firstly, the second rotating shaft 12 should be operated to make the switching sheet 15 move towards the second cam 122, next, the first rotating shaft 11 is rotated, finally, the double-shaft hinge 10 is closed.

The carrier frame 13 is provided with the limiting passage 132, so that the switching sheet 15 is limited by the limiting passage 132 to make the linear movement 151 along the surface of the carrier frame 13, thereby preventing the switching sheet 15 from falling off of the carrier frame 13. Moreover, the double-shaft hinge 10 of the present invention has better structural stability and gives a better experience to the user.

In an embodiment, referring to FIG. 1, FIG. 2, FIG. 3, FIG. 4, and FIG. 5, the carrier frame 13 comprises a main body 134, two retaining walls 135 and a cover 136. Specifically, the main body 134 is formed with two shaft installation holes 131 and is connected with the first rotating shaft 11 and the second rotating shaft 12. The two retaining walls 135 are arranged on the main body 134 and both located between the two shaft installation holes 131. The two retaining walls 135 extend towards one side of the carrier frame 13 and are parallel to the linear movement 151, thereby limiting the moving direction of the switching sheet 15. Further, the cover 136 is connected with the two retaining walls 135. The cover 136 is arranged at one side of the switching sheet 15 that is not in contact with the main body 134. In the present embodiment, the cover 136, the two retaining walls 135 and the main body 134 are one-piece formed. The cover 136, the two retaining walls 135, the main body 134 jointly define the limiting passage 132. In an embodiment, a distance between the cover 136 and the main body 134 defines a height 137 of the limiting passage 132. In order to enable the switching sheet 15 to make the linear movement 151 in the limiting passage 132, the height 137 of the limiting passage 132 is set to be greater than or equal to the thickness 152 of the switching sheet 15.

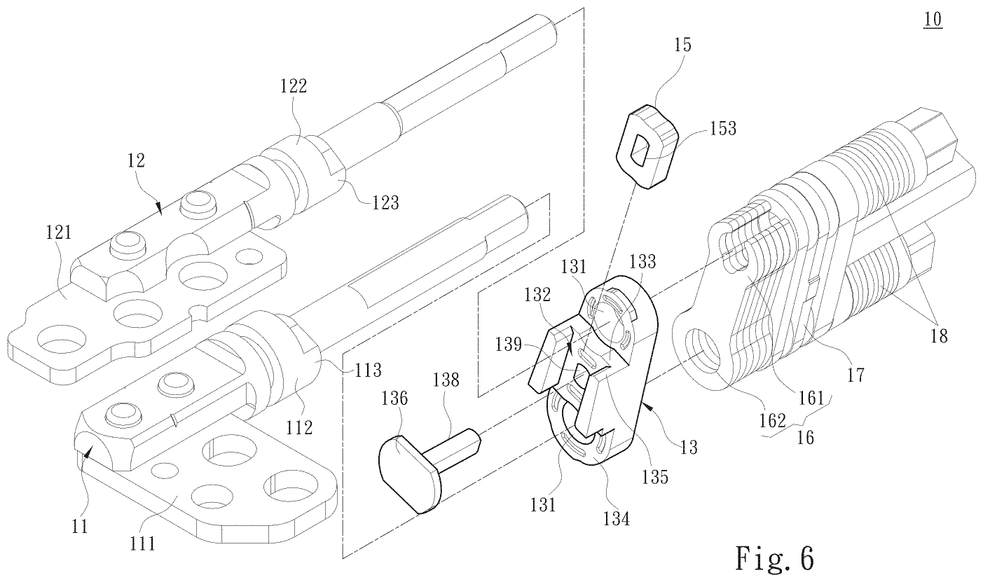

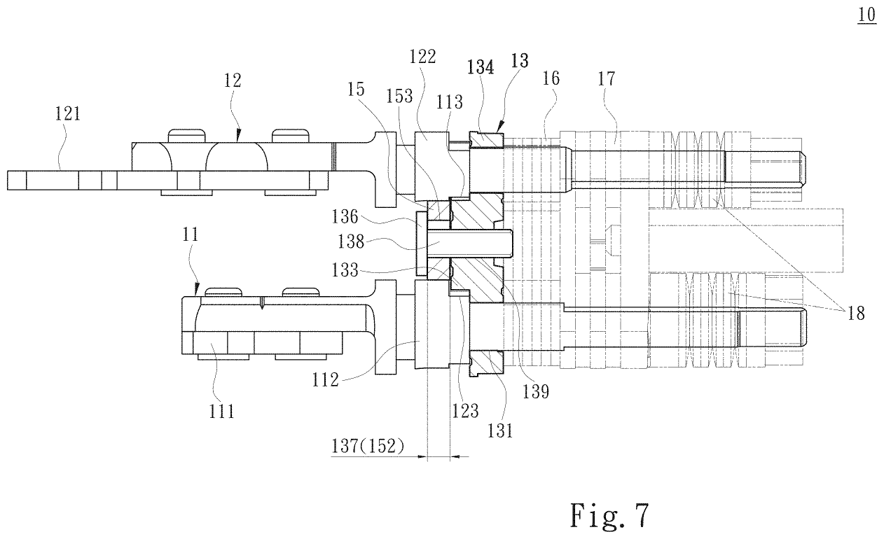

In an embodiment, referring to FIG. 6 and FIG. 7, the cover 136 has an independent structure with respect to the two retaining walls 135 and the main body 134. In the present embodiment, the cover 136 limits the switching sheet 15 to make the linear movement 151 only along the surface of the carrier frame 13, and the cover 136 is provided with a convex column 138 extending towards the switching sheet 15. The switching sheet 15 is formed with an elongated hole 153 used for the convex column 138 to pass through. The main body 134 is formed with a through hole 139 arranged between the two shaft installation holes 131 for the convex column 138 to enter therein via the elongated hole 153. Further, the convex column 138 changes the position in the elongated hole 153 when the switching sheet 15 makes the linear movement 151. Specifically, when the switching sheet 15 moves towards the second rotating shaft 12 in response to rotation of the first rotating shaft 11, the convex column 138 moves between two sides of the elongated hole 153, which changes from contacting one side adjacent to the first cam 112 to contacting one side adjacent to the second cam 122. Further, when the switching sheet 15 moves towards the first rotating shaft 11 in response to rotation of the second rotating shaft 12, the convex column 138 moves between two sides of the elongated hole 153, which changes from contacting one side adjacent to the second cam 122 to contacting one side adjacent to the first cam 112.

In an embodiment, referring to FIG. 1, FIG. 2, FIG. 3, FIG. 4, and FIG. 5, the first cam 112 and the second cam 122 are respectively provided with a rotation limiting block 113 and 123. One side of the carrier frame 13 is provided with two retaining blocks 133 facing the first cam 112 and the second cam 122 respectively. In detail, the two rotation limiting blocks 113 and 123 are arranged at the first cam 112 and the second cam 122 respectively facing one side of the carrier frame 13. In the present embodiment, the two rotation limiting blocks 113 and 123 are one-piece formed with the first cam 112 and the second cam 122 respectively, rather than having an independent structure with respect to the first cam 112 and the second cam 122 in the conventional technique. Furthermore, the two retaining blocks 133 are located on rotation routes of the first cam 112 and the second cam 122 respectively. When the first rotating shaft 11 is forced to rotate, the rotation limiting block 113 on the first cam 112 pushes against the retaining block 133, and then the rotation limiting block 113 is matched with the retaining block 133 to jointly limit the rotation of the first rotating shaft 11. When the second rotating shaft 12 is forced to rotate, the rotation limiting block 123 on the second cam 122 is also forced by the retaining block 133, so that the rotation limiting block 123 is matched with the retaining block 133 to jointly limit the rotation of the second rotating shaft 12.

Further in another aspect, referring to FIG. 1, FIG. 2, FIG. 3, FIG. 4, FIG. 5, FIG. 6, and FIG. 7, in an embodiment, in order to increase the torsion when opening or closing the double-shaft hinge 10, the double-shaft hinge 10 comprises at least one torsion generating member 16. The at least one torsion generating member 16 is arranged at one side of the carrier frame 13 not facing the switching sheet 15 and is connected with the first rotating shaft 11 and the second rotating shaft 12. Further, the torsion generating member 16 is provided with a connecting arm 161 and an open hole 162 at two sides respectively. The connecting arm 161 is connected with one of the first rotating shaft 11 and the second rotating shaft 12. The open hole 162 is used for the other one of the first rotating shaft 11 and the second rotating shaft 12 to pass through. Further in another embodiment, the double-shaft hinge 10 is provided with at least one connecting sheet 17 and two torsion spring groups 18. The at least one connecting sheet 17 is connected with the first rotating shaft 11 and the second rotating shaft 12. The two torsion spring groups 18 are arranged at one side of the first rotating shaft 11 that is not provided with the first assembling plate 111 and arranged at one side of the second rotating shaft 12 that is not provided with the second assembling plate 121. The connecting sheet 17 is connected with the first rotating shaft 1I and the second rotating shaft 12 to keep stable. The torsion spring groups 18 provide the torsion when opening or closing the double-shaft hinge 10.

What is claimed is:

1. A double-shaft hinge with a stable structure, comprising:
a first rotating shaft, provided with a first cam;
a second rotating shaft, parallel to the first rotating shaft and provided with a second cam;
a carrier frame, formed with a limiting passage and two shaft installation holes arranged at intervals and used respectively for the first rotating shaft and the second rotating shaft to pass through, wherein openings in two ends of the limiting passage face the first cam and the second cam respectively; and
a switching sheet, arranged on the carrier frame and limited by the limiting passage to make a linear movement only along a surface of the carrier frame, wherein the switching sheet comprises a first state of being pushed by the first cam to limit rotation of the second rotating shaft, and a second state of being pushed by the second cam to limit rotation of the first rotating shaft.

2. The double-shaft hinge with the stable structure according to claim 1, wherein the carrier frame comprises a main body formed with the two shaft installation holes, two retaining walls located respectively between the two shaft installation holes and parallel to the linear movement, and a cover disposed on the two retaining walls, and the main body, the two retaining walls and the cover jointly define the limiting passage.

3. The double-shaft hinge with the stable structure according to claim 2, wherein the main body is formed with a through hole arranged between the two shaft installation holes, the switching sheet is formed with an elongated hole, the cover is provided with a convex column extending into the through hole via the elongated hole, and a position of the convex column in the elongated hole is changed when the switching sheet makes the linear movement.

4. The double-shaft hinge with the stable structure according to claim 1, wherein the first cam and the second cam are provided respectively with a rotation limiting block at one side facing the main body, and the carrier frame is provided with a retaining block matched with the rotation limiting block respectively at one sides facing the first cam and the second cam.

5. The double-shaft hinge with the stable structure according to claim 4, wherein a height of the limiting passage is greater than or equal to a thickness of the switching sheet.

6. The double-shaft hinge with the stable structure according to claim 5, wherein the double-shaft hinge is provided with at least one torsion generating member arranged at one side of the carrier frame and connected with the first rotating shaft and the second rotating shaft; and the at least one torsion generating member is provided with a connecting arm connected with one of the first rotating shaft and the second rotating shaft, and an open hole used for the other one of the first rotating shaft and the second rotating shaft to pass through.

7. The double-shaft hinge with the stable structure according to claim 6, wherein the double-shaft hinge is provided with at least one connecting sheet connected with the first rotating shaft and the second rotating shaft and two torsion spring groups arranged respectively on the first rotating shaft and the second rotating shaft.

8. The double-shaft hinge with the stable structure according to claim 1, wherein a height of the limiting passage is greater than or equal to a thickness of the switching sheet.

9. The double-shaft hinge with the stable structure according to claim 8, wherein the double-shaft hinge is provided with at least one torsion generating member arranged at one side of the carrier frame and connected with the first rotating shaft and the second rotating shaft, and the torsion generating member is provided with a connecting arm connected with one of the first rotating shaft and the second rotating shaft, and an open hole used for the other one of the first rotating shaft and the second rotating shaft to pass through.
